(19) United States
(12) Patent Application Publication
(10) Pub. No.: US 2017/0207642 A1
(43) Pub. Date: Jul. 20, 2017

(54) E-FUSE/SWITCH BY BACK END OF LINE (BEOL) PROCESS

(71) Applicant: Renesas Electronics America Inc., Santa Clara, CA (US)

(72) Inventors: Tetsuo Sato, San Jose, CA (US); Shigeru Maeta, San Jose, CA (US); Toshio Kimura, Cupertino, CA (US); Kenji Yoshida, Cupertino, CA (US)

(21) Appl. No.: 15/406,288

(22) Filed: Jan. 13, 2017

Related U.S. Application Data
(60) Provisional application No. 62/279,198, filed on Jan. 15, 2016.

(51) Int. Cl. H02J 7/00; H01L 29/786

(52) U.S. Cl. CPC H02J 7/0031; H02J 7/0068; H01L 29/7869; H02J 7/0072; H02J 2007/0037

(57) ABSTRACT

An apparatus and method for use in devices such as rechargeable battery packs. The apparatus, in one embodiment, includes an integrated circuit comprising a first circuit, a second circuit, and a thin film transistor (TFT). The first circuit is configured to generate a square wave signal. The second circuit is configured to convert the square wave signal to a direct current (DC) signal. The TFT is configured to activate and conduct current in response to the DC control signal.

### RELATED APPLICATIONS

This application claims the domestic benefit under Title 35 of the United States Code §119(e) of U.S. Provisional Patent Application Ser. No. 62/279,198, entitled “E-Fuse/Switch by Back End of Line (BEOL) Process,” filed Jan. 16, 2016, which is hereby incorporated by reference in its entirety and for all purposes as if completely and fully set forth herein.

### BACKGROUND OF THE INVENTION

Lithium-ion battery packs are commonly used as power sources for mobile devices such as smart phones, notebook computers, cameras, etc. For purposes of explanation only, the present invention will be described with reference to lithium-ion battery packs (hereinafter battery packs) for use in notebook computers, it being understood the present invention should not be limited thereto.

The battery packs contain lithium-ion cells that can be charged and recharged many times. Lithium-ion cells can be dangerous if subjected to unsafe operating conditions such as over-charging, over-discharging, excessive current, high temperatures, etc. Unsafe operating conditions can lead to battery pack smoke or fire.

Battery packs employ internal primary and secondary protection systems to protect the lithium-ion cells. These protection systems monitor the cells for unsafe operating conditions. If an unsafe operating condition is detected, the primary protection system or the secondary system shuts down the lithium-ion cells. The secondary system operates independently of the primary protection system. If the primary protections system fails to act when an unsafe operating condition is detected, the secondary protection system will shut down the lithium-ion cells.

Battery packs operate in charge mode or discharge mode. In the charge mode, electrical current flows into the battery pack and charges one or more lithium-ion cells via an activated charge MOSFET (C-FET). In the discharge mode, current flows out of the cells via an activated discharge MOSFET (D-FET) to power a notebook computer. The primary protection system includes a fuel-gauge and primary protection IC (hereinafter FG-IC), which monitors the cells. The FG-IC shuts down the cells by deactivating the C-FET and/or D-FET, which interrupts current flow into or out of the cells when the FG-IC detects an unsafe operating condition. Once the unsafe operating condition is resolved, the FG-IC can reactivate the C-FET and/or D-FET.

The FG-IC, C-FET, and/or D-FET can fail if damaged by, for example, an unexpected electrical surge. As noted above, the secondary protection system acts as a failsafe to the FG-IC. The secondary protection system includes a secondary protection IC that monitors the lithium-ion cells for unsafe operating conditions. If the secondary protection IC detects severe over-charging or another unsafe operating condition, the secondary protection IC permanently shuts down the cells by cutting a fuse, such as a chemical fuse manufactured and sold by Dexerials Corporation of Japan. Current cannot flow into or out of the cells via the fuse once it is cut.

### SUMMARY OF THE INVENTION

An apparatus and method for use in devices such as battery packs. The apparatus, in one embodiment, includes an integrated circuit comprising a first circuit, a second circuit, and a thin film transistor (TFT). The first circuit is configured to generate a square wave signal or other periodic signal. The second circuit is configured to convert the square wave signal to a direct current (DC) control signal. The TFT is configured to activate and conduct current in response to the DC control signal.

### BRIEF DESCRIPTION OF THE DRAWINGS

The present invention may be better understood in its numerous objects, features, and advantages made apparent to those skilled in the art by referencing the accompanying drawings.

FIG. 1 is a block diagram illustrating an example battery pack that employs primary and secondary protection systems.

FIG. 2 is a block diagram illustrating an example battery pack that employs primary and secondary protection systems according to an embodiment of the present invention.

FIG. 3 is a timing diagram that shows a relationship between a clock signal and the active/inactive state of an e-Fuse according to an embodiment of the present invention.

FIG. 4 is a drawing that represents a cross section of an example fuel gauge and primary protection integrated circuit employed in FIG. 2 or 5.

FIG. 5 is a block diagram illustrating another example battery pack that employs primary and secondary protection systems according to an embodiment of the present invention.

FIG. 6 is circuit diagram illustrating an example thin film transistor activation circuit employed in FIGS. 2 and 5.

FIG. 7 is circuit diagram illustrating another example of the thin film transistor activation circuit employed in FIGS. 2 and 5.

The use of the same reference symbols in different drawings indicates similar or identical items.

### DETAILED DESCRIPTION

FIG. 1 illustrates an example battery pack 100 that employs primary and secondary protection systems. Battery pack 100 includes rechargeable lithium-ion battery cells (cells) 102, F/G-IC 104, C-FET 106, D-FET 108, power MOSFET 110, fuse 112, secondary protection IC 114, OR gate 116, and sense resistor R. Additional components such as a thermistor coupled to the FG-IC 104 and/or cells 102 are not shown.

The components of battery pack 100 are coupled between a pair of battery pack terminals Vcc and Vgnd. Current for charging or discharging cells 102 flow into or out of battery pack 100 via terminals Vcc and Vgnd. All components of battery pack 100 shown in FIG. 1, except for cells 102, are mounted on a printed circuit board (PCB, not shown) and connected together as shown via metal traces formed thereon. The PCB is small (e.g., 100 mm×10 mm) in order for it to fit inside a small battery pack housing of a notebook computer.

Battery pack 100 includes primary and secondary protection systems that protect cells 102 from over-charging, over-discharging, excessive temperatures, excessive load current or other unsafe operating conditions. The primary protection system includes FG-IC 104. The secondary protection system includes secondary protection IC 114.

FG-IC 104 controls power C-FET 106, D-FET 108 and power MOSFET 110. Secondary protection circuit 114 controls power MOSFET 110. As will be more fully described, FG-IC 104 or secondary protection circuit 114 can cut fuse 112 by activating power MOSFET 110 via OR gate 116.

FG-IC 104 asserts and holds control signals C and D in order to activate C-FET 106 and D-FET 108, respectively. C-FET 106 and D-FET 108 transmit current for charging or discharging cells 102 when activated. FG-IC 104 activates C-FET 106 during the charging mode of battery pack 100 operation, and FG-IC 104 activates D-FET 108 during the discharging mode of operation. While battery pack is being charged or discharged, FG-IC 104 monitors for unsafe conditions by comparing primary programmed limits against operational parameters such as the voltage(s) across cells 102, cell temperature, current flow through sense resistor R, etc. FG-IC 104 can shut down cells 102 by deactivating C-FET 106 and/or D-FET if any of the operational parameters exceed or drop below their corresponding primary programmed limits. In addition, as will be more fully described below, FG-IC 104 can cut fuse 112 if an unsafe operating condition is detected.

Secondary protection circuit 114 also monitors cells 102 while they are being charged or discharged. Secondary protection circuit 114 monitors cells 102 by comparing secondary programmed limits against operational parameters such as the voltage(s) across cells 102. Secondary protection circuit 114 can cut fuse 112 if any of the operational parameters it monitors, exceed or fall below their corresponding secondary programmed limits. Corresponding primary and secondary programmed limits are set to different values. To illustrate, FG-IC 104 compares the collective voltage across cells 102 against a primary programmed voltage limit, while secondary protection circuit 114 compares the collective voltage against a secondary programmed voltage limit, which is greater than the primary programmed voltage limit. In this configuration, FG-IC 104 should deactivate C-FET 106 to protect cells 102 from over-charging before secondary protection circuit 114 activates power MOSFET 110. If FG-IC 104 is not operating properly, however, secondary protection circuit 114 will activate MOSFET 110 and cut fuse when the collective voltage of cells 102 exceed the secondary programmed voltage limit.

Power MOSFET 110 is controlled by FG-IC 104 and secondary protection IC 114. Importantly, fuse 112 is cut when MOSFET 110 is activated by either FG-IC 104 or secondary protection IC 114 as will be described below. FG-IC 104 may activate MOSFET 110 when FG-IC 104 determines it is incapable of deactivating C-FET 106 and C-FET D-FET 108. For example, FG-IC 104 can activate MOSFET 110 by asserting and holding a primary error control signal PE when FG-IC 104 determines current continues to flow through resistor R after FG-IC 104 de-asserts control signals C and/or D. As noted above, secondary protection IC monitors cells 102 for unsafe operating conditions such as over-charging. Secondary protection IC 114 can activate MOSFET 110 by asserting and holding secondary error control signal SE when secondary protection IC 114 detects a severely unsafe operating condition.

Fuse 112 includes a heater element 118 and a fuse element 120. Fuse element 120 is coupled in series between D-FET 108 and cells 102 as shown. Fuse element 120 is rated to conduct current up to a limit (e.g., 5-10 amps) when battery pack 100 is being charged or discharged. Heater element 118 can be activated by either F/G-IC 104 or secondary protection IC 114 via power MOSFET 110. When an unsafe operating condition is detected, FG-IC 104 or secondary protection IC 114 can assert and hold primary error signal PE or secondary error signal SE, respectively, which activates MOSFET 110 via OR gate 116. Activated MOSFET 110 enables current flow (e.g., 50 amps) through heater element 118, which in turn causes heater element 118 to quickly heat and melt (i.e., cut) fuse element 120. Electric current cannot flow through fuse element 120 after it has been cut. Battery pack 100 is essentially unusable after fuse element 120 is cut.

F/G-IC 104 may take form in a microcontroller that includes several components (not shown) such as a CPU, memory that stores instructions executable by the CPU, analog-to-digital converters (ADCs), comparators, timers, I/O pads, etc. Secondary protection IC may take form in a simple comparator IC that compares secondary programmed limits to operational parameters like the voltage(s) across cells 102. Integrated circuits like FG-IC 104 are fabricated using a front-end-of-line (FEOL) process and a back-end-of-line (BEOL) process. FEOL is the first portion of IC fabrication where individual devices (transistors, capacitors, resistors, etc.) are patterned in a semiconductor wafer. FEOL may include the formation of polysilicon that locally interconnects devices that are very close to each other. FEOL generally covers everything up to (but not including) the deposition of metal interconnect layers. BEOL is the second portion of IC fabrication where devices are globally interconnected with metal wiring. BEOL generally begins when the first layer of metal is deposited on the wafer. BEOL includes the formation of contacts or vias, insulating layers (dielectrics), metal wiring, and bonding sites. Ten or more metal interconnect layers can be added during the BEOL portion of IC fabrication. The top-most layers have the thickest, widest and most widely-separated metal wires, which make them very well suited for power or clock distribution since they have the least resistance and smallest RC time delay.

The primary and secondary protection systems of FIG. 1 adequately protect cells 102. However, there are several disadvantages to these protection systems. For example fuse 112, C-FET 106, D-FET 108, power MOSFET 110, and/or OR gate are expensive to make or purchase. These components, the FG-IC 104, resistor R, and the secondary protection IC are mounted on a PCB. This PCB must have a large surface area (e.g., at least 100 mm×10 mm) to receive these components. A large PCB may pose a problem for battery packs that must fit inside the small confines of a notebook computer. It is also expensive to mount fuse 112, C-FET 106, D-FET 108, power MOSFET 110, and/or OR gate on the battery pack PCB during final assembly. Once fuse element 120 is cut, rechargeable battery pack 100 is essentially unusable. C-FET 106 and D-FET 108 each have a body diode BD 130. The body diode requires at least two FETs (C-FET 106 and D-FET 108 connected in series to accommodate bidirectional current flow into and out of cells 102. Should cells 102 discharge to a low enough state, cells 102 may not be able to produce enough current (e.g., 50 amps) to cut fuse 112. Additional disadvantages are contemplated.

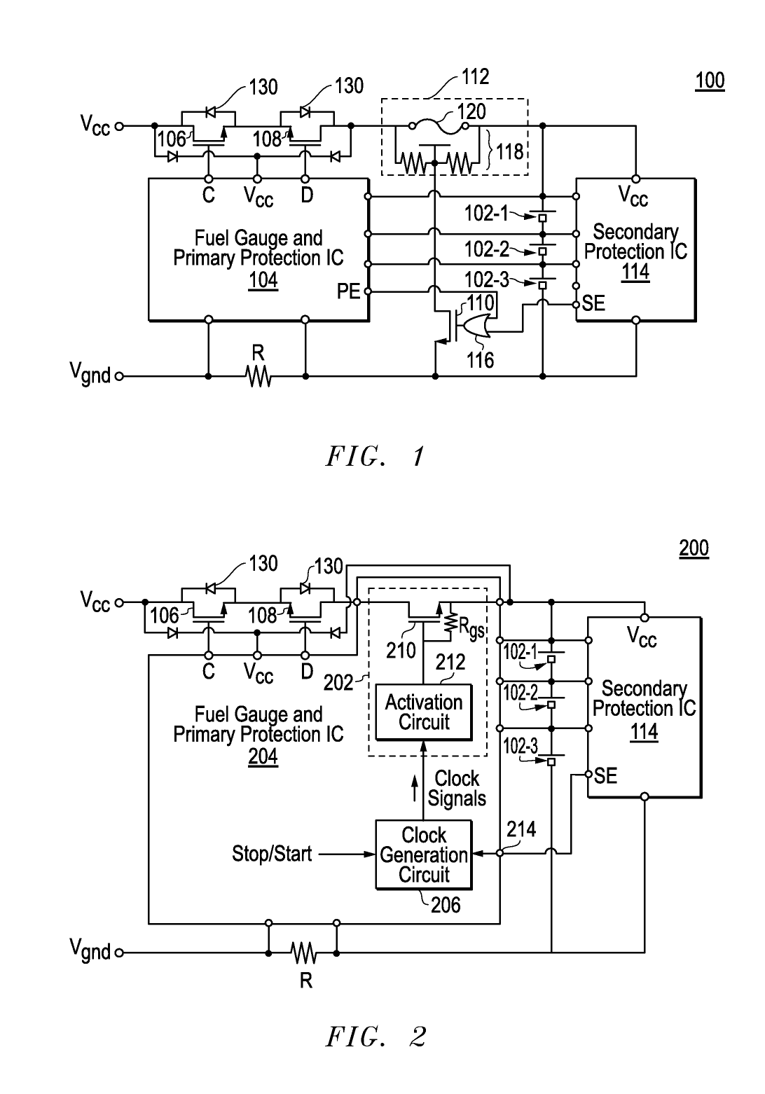

The present invention provides an alternative primary and/or secondary protection system. FIG. 2 illustrates a battery pack 200 employing one embodiment of the present invention. Battery pack 200 includes many of the same components of battery pack 100. For example, battery pack 200 includes cells 102, secondary protection IC 114, sense resistor R, power C-FET 106, and D-FET 108. Substantial differences, however, exist between battery pack 100 and battery pack 200. Most notably, battery pack 200 lacks fuse 112, power MOSFET 110, and OR gate 116. The lack of these components reduces the cost of battery pack 200 and provides other advantages over battery pack 100.

Battery pack 200 includes FG-IC 204, which is similar in many ways to FG-IC 104. FG-IC 204 takes form in a microcontroller that includes several components (not shown) such as a CPU, memory that stores instructions executable by the CPU, ADCs, comparators, timers, I/O pads, etc. Like FG-IC 104, FG-IC IC 204 monitors operating parameters such as current flow through sense resistor R, voltage(s) across battery cells 102, temperature, etc. If FG-IC 204 detects that one or more of these parameters have exceeded or dropped below a corresponding primary programmed limit while cells 102 are charging or discharging, FG-IC 204 can shut down cells 102 by deactivating C-FET 106 and/or D-FET 108.

While FG-IC 104 and FG-IC 204 are similar in many ways, substantial differences exist. Most notably, FG-IC 204 includes an e-Fuse 202, which is coupled in series with cells 102 as shown. E-Fuse 202, when activated, conducts charging or discharging current to or from cells 102. As will be more fully described below, e-Fuse 202 includes a thin film transistor (TFT) 210, resistor Rgs, and an activation circuit 212. In general a TFT is a special kind of FET made by depositing a thin film of an active semiconductor layer as well as a dielectric layer and metallic contacts over a supporting (but non-conducting) substrate.

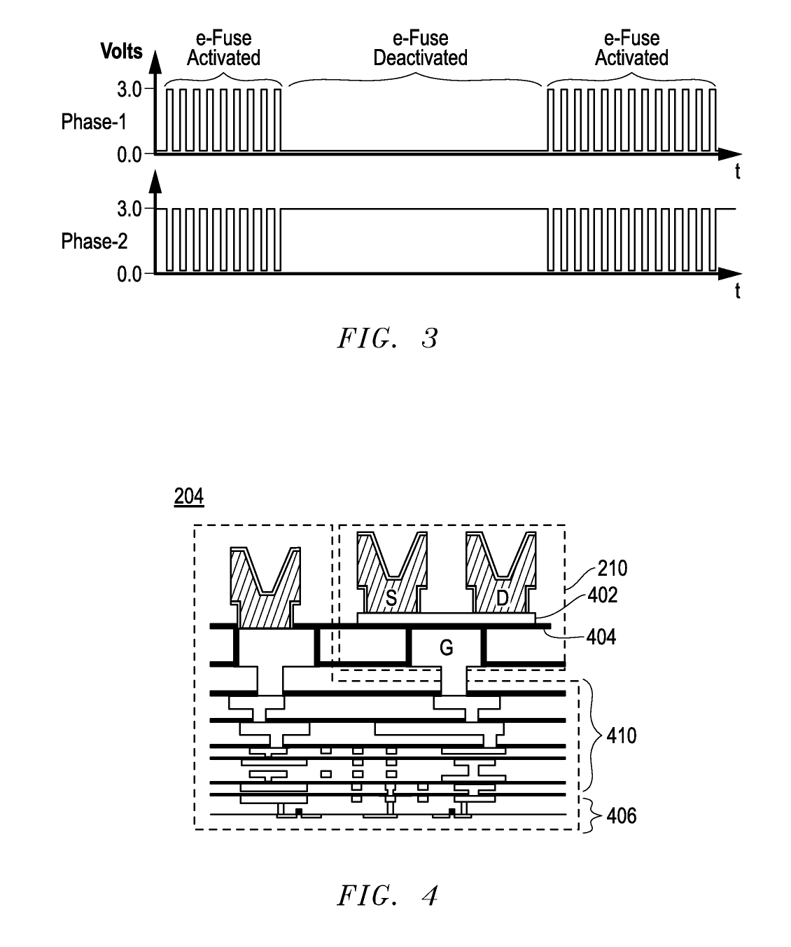

FG-IC 204 also includes a periodic signal generation circuit 206, which generates a periodic signal (e.g., a square wave signal, a two-phase clock signal, a sinusoidal signal, pulse width modulation (PWM) signal, etc.) for e-Fuse 202. For purposes of explanation periodic signal generation circuit 206 takes form in a clock generator that generates non-overlapping, clock signals (phase-1 and phase-2), except where noted herein. E-Fuse 202 conducts current to or from cells 102 only when e-Fuse 202 receives the two-phase clock signals from clock signal generation circuit 206. FIG. 3 illustrates the relationship between phase-1, phase-2, and e-Fuse 202 control. As seen, e-Fuse 202 is activated only while the clock signals are continuously generated. Without the clock signals, e-fuse 202 will not conduct current to or from cells 102.

Clock generator 206 is controlled internally and externally. For example, clock generator 206 generates the clock signals for e-Fuse 202 after clock generator 206 receives a start signal that is internally generated by the CPU, a timer, a counter, a comparator, etc., (not shown) of FG-IC 204. And clock generator 206 continues to generate the clock signals for e-Fuse 202 until clock generator 206 receives an internally generated stop signal (i.e., a stop signal generated by the CPU, a comparator, a timer, a counter, etc., of FG-IC 204). The stop signal is generated when FG-IC 204 detects an unsafe operating condition such as excessive current through resistor R. Clock generator 206 is also subject to external control. For example, clock generator 206 will discontinue clock signal generation after it directly receives the secondary error signal SE from secondary protection circuit 114 via I/O pad 214.

If core components (e.g., the CPU, comparators, timers, counters, etc.) of FG-IC 204 are incapable of generating the start signal for clock generator 206 because of physical damage or because of software error, then clock generator 206 will not generate the clock signals, and as a result e-Fuse 202 cannot be activated to conduct charge or discharge current. Or, if clock generator 206 is damaged and incapable of generating the clock signals after receiving a start signal, then e-Fuse 202 cannot be activated to charge or discharge cells 102. Sudden damage (i.e., damage from a sudden and unexpected current surge) or software error could also disable FG-IC 204's ability to internally generate a stop signal while cells 102 are charging or discharging. Or sudden damage could disable clock generator 206's ability to discontinue clock signal generation after clock generator 206 receives a stop signal. Either scenario could lead to free run generation of the clock signals while cells 102 are subjected to unsafe operating conditions. As a failsafe protection against free running clock signals and damage to cells 102 that can result therefrom, clock generator 206 is configured to discontinue clock signal generation in response directly receiving the secondary error signal SE from secondary protection circuit 114 via I/O pad 214.

Like FG-IC 104, FG-IC 204 is fabricated using FEOL and BEOL. Most of the components, including clock generator 206, are formed during the FEOL portion of FG-IC 204 fabrication. E-Fuse 202 is partially or fully formed during the BEOL portion of FG-IC 204 fabrication. As noted, e-Fuse 202 includes a TFT 210, resistor Rgs, and an activation circuit 212. In one embodiment, TFT 210, Rgs, and activation circuit 212 are all formed during the BEOL portion of FG-IC 204 fabrication. In another embodiment, only TFT 210 is formed during BEOL of FG-IC 204 fabrication, while Rgs and activation circuit 212 are formed during the FEOL portion. For purposes of explanation, it will be presumed TFT 210, resistor Rgs, and activation circuit 212 are all formed on FG-IC 204 during BEOL. Sense resistor R can also be formed on FG-IC 204 during the BEOL portion of fabrication.

TFT 210 is fabricated with an active semiconductor layer of wide band-gap InGaZnO, it being understood that alternative semiconductor layers are contemplated. TFT 210 lacks a body diode. U.S. Pat. No. 9,082,643, and Kaneko, K. et.al., “A Novel BEOL-Transistor (BETr) with InGaZnO Embedded in Cu-Interconnects for On-chip High Voltage I/Os in Standard CMOS LSIs”, 2011 Symposium on VLSI Technology Digest of Technical Papers, pp. 120-121 (2011), both of which are incorporated herein by reference, describe at least one example method for forming devices such as TFT 210 during the BEOL process.

FIG. 4 represents a cross sectional view of an example FG-IC 204. TFT 210 includes a thin layer 402 of InGaZnO or other semiconductor material, an insulating layer 404 that separates the InGaZnO layer from a copper gate G, an aluminum source S and an aluminum drain D. TFT 210 is fabricated using the top two BEOL pattern layers. The FEOL formed components 406 (e.g., CPU, timers, comparators, etc.) of the FG-IC 204 core are separated from TFT 210 by several layers 410 of metal interconnect, which are also created using the BEOL process. As seen in FIG. 4, the size of the metal interconnects increase. Although not shown, the activation circuit 212 and Rgs are also created in the top two layers during the BEOL process.

TFT 210 has several features that make it well suited for use as a safety device in a battery pack such as battery pack 200, including: a high drain/source breakdown voltage BVds (e.g., BVds>40 volts); low Rdson (e.g.,Rdson<5 mohm); isolation from the silicon die; no body diode; when BVds is exceeded an open circuit results between the drain and source, etc. Other advantages are contemplated as more fully described below.

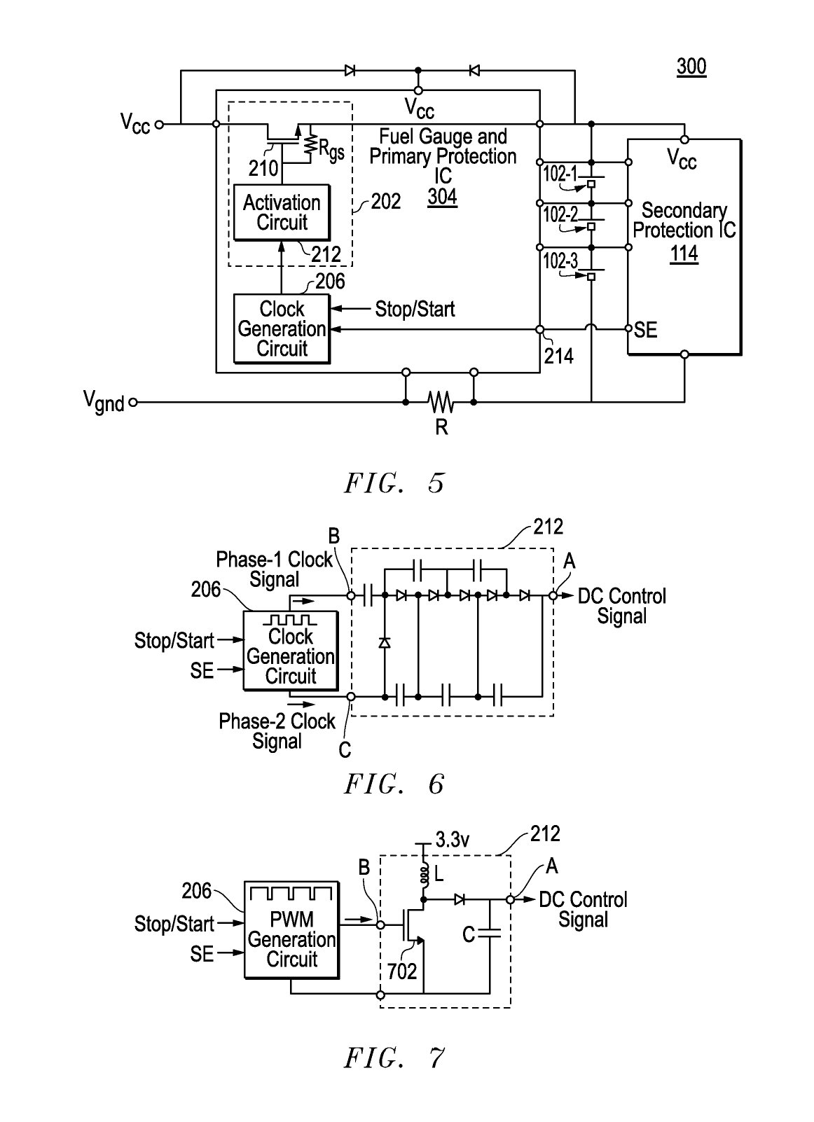

FIG. 5 illustrates battery pack 300 employing another embodiment of the present invention. Battery pack 300 includes many of the components of battery pack 200, including cells 102 and secondary protection IC 114. Battery pack 300 also includes FG-IC 304 coupled to cells 102 and secondary protection circuit 114. FG-IC 304 is nearly identical to FG-IC 204 described above. Unlike battery pack 200 of FIG. 2, battery pack 300 lacks C-FET 106 and D-FET 108. FG-IC 304 is simplified compared to FG-IC 204 in that FG-IC 304 need not generate control signals C and D. Also, since TFT 210 lacks a body diode, a single TFT 210 controls current flow in both directions (i.e., charge and discharge); in contrast both C-FET 106 and D-FET 108 in FIG. 2 are needed to control bidirectional current flow. Other advantages are contemplated. The surface area of the PCB needed for battery pack 300 can be reduced because of the lack of C-FET 106 and D-FET 108.

Activation circuit 212 is employed in FG-IC 204 and FG-IC 304. Activation circuit 212 converts the clock signals from clock generation circuit 206 into a DC control signal that can activate TFT 210. The DC control signal must have a DC component of sufficient magnitude to activate and continue to activate TFT 210 while cells 102 are fully charged. In other words, the AC components of the DC control signal should not intermittently deactivate TFT 210.

Activation circuit 212 can be configured as a voltage multiplier, a boost converter, etc. FIG. 6 illustrates an example voltage multiplier that includes capacitors and diodes connected as shown. Input terminals B and C receive the clock signals (i.e., non-overlapping phase-1 and phase-2 clock signals) from the clock generator 206. In response to receiving the clock signals, the voltage multiplier shown in FIG. 6 generates the DC control signal at output node A, which in turn drives the gate G of TFT 210. The operating principle of voltage multipliers is well known in the art. Capacitors connected in series are charged and discharged on alternate half-cycles of the clock signals. Rectifiers and additional capacitors are used to force equal voltage increments across each of these series capacitors. The multiplier circuit's output voltage is simply the sum of these series capacitor voltages. In FIG. 6, the DC control signal output at A will be approximately 18.0 volts with 3.3 volt peak-to-peak clock signal input at B and C. A DC control signal of 18.0 volts is more than sufficient to activate TFT 210, even when cells 102 are fully charged at 12.6 volts, since the threshold voltage of TFT is approximately 3.0 volts. As long as the clock signals are received, the voltage multiplier of FIG. 6 generates the DC control signal maintains TFT 210 in the active state. However, without the clock signals the voltage multiplier shown in FIG. 6 will not generate a DC control signal that can activate TFT 210. In other words, if activation circuit 212 does not continuously receive the clock signals, activation circuit 212 will not generate a DC control signal that activates TFT 210.

FIG. 7 illustrates an example boost converter that can be employed to activate TFT 210. Boost converters are well known in the art. A boost converter is a DC-to-DC power converter with an output voltage greater than its input voltage. It is a class of switched-mode power supply (SMPS) containing at least two semiconductors (a diode and a transistor) and at least one energy storage element, a capacitor, inductor, or the two in combination. In this embodiment, generator 206 does not generate two-phase clock signals. Rather, generator 206 generates a PWM signal with, for example, an 80% duty cycle for the boost converter. MOSFET 702 receives the PWM signal and a DC input voltage of 3.3 volts. The boost converter generates an output DC control signal that is greater in magnitude than the input DC voltage. With the 80% duty cycle and an input DC voltage of 3.3 volts, the boost converter shown in FIG. 7 generates a DC control signal at 19.5 volts, which is more than sufficient to maintain TFT 210 in the active state. As long as the PWM signal is received, the boost converter of FIG. 7 generates the DC control signal that maintains TFT 210 in the active state. However, without the PWM signal (i.e., with a DC input to the gate of MOSFET 702) the voltage multiplier shown in FIG. 6 will not generate a DC control signal at A that can activate TFT 210.

Although the present invention has been described in connection with several embodiments, the invention is not intended to be limited to the specific forms set forth herein. On the contrary, it is intended to cover such alternatives, modifications, and equivalents as can be reasonably included within the scope of the invention as defined by the appended claims.

What is claimed is:

1. An apparatus comprising:
an integrated circuit comprising a first circuit, a second circuit, and a thin film transistor (TFT);
wherein the first circuit is configured to generate a first periodic signal;
wherein the second circuit is configured to generate a direct current (DC) signal based on the first periodic signal;
wherein the TFT is configured to activate and conduct current in response to the DC control signal.

2. The apparatus of claim 1 wherein the TFT is formed on the integrated circuit using a back end of line (BEOL) process and wherein the first circuit is formed on the integrated circuit using a front end of line (FEOL) process.

3. The apparatus of claim 1 wherein the TFT comprises an InGaZnO MOSFET.

4. The apparatus of claim 1 further comprising a rechargeable battery cell, wherein the TFT, when activated by the DC control signal, conducts current to or from the rechargeable battery cell.

5. The apparatus of claim 1 wherein the first circuit generates a second periodic signal, wherein the second circuit generates the DC control signal based on the first and second periodic signals.

6. The apparatus of claim 2 wherein the second circuit is formed on the integrated circuit using the BEOL process.

7. The apparatus of claim 2 wherein the second circuit is formed on the integrated circuit using the FEOL process.

8. The apparatus of claim 1 wherein the TFT lacks a body diode.

9. A method comprising:
a first circuit generating a first periodic signal;
a second circuit converting the first periodic signal into a DC control signal;
a TFT conducting current to or from a rechargeable battery cell while the second circuit converts the first periodic signal into the DC control signal.

10. The method of claim 9 wherein the TFT is formed on an integrated circuit using a back end of line (BEOL) process and wherein the first circuit is formed on the integrated circuit using a front end of line (FEOL) process.

11. The method of claim 10 wherein the TFT comprises an InGaZnO MOSFET.

12. The method of claim 10 wherein the second circuit comprises a charge pump circuit, a multiplying voltage rectifier, or a DC-DC up converter.

13. The method of claim 10 wherein the second circuit is formed on the integrated circuit using the BEOL process.

14. The method of claim 10 wherein the second circuit is formed on the integrated circuit using the FEOL process.

15. The method of claim 10 wherein the TFT lacks a body diode.

16. The method of claim 9 wherein the first circuit generates first and second periodic signals, wherein the second circuit converts the first and second periodic signals into the DC control signal.

17. An apparatus comprising:
a battery cell;
a microcontroller comprising a first circuit, a second circuit, and a TFT;
wherein the first circuit is configured to generate a first periodic signal;
wherein the second circuit is configured to convert the first periodic signal into a DC control signal;
wherein the TFT is configured to transmit current to or from the battery cell in response to the conversion of the first periodic signal into the DC control signal.

18. The apparatus of claim 17 wherein the microcontroller is coupled to and configured to monitor operating characteristics of the battery cell.

19. The apparatus of claim 17 wherein the TFT is formed on the microcontroller using a BEOL process, and wherein the first circuit is formed on the microcontroller using a FEOL process.

20. The apparatus of claim 17 wherein a plurality of metallization layers are positioned between the first circuit and the TFT, where in each of the metallization layers include.
